(19) United States
(12) Patent Application Publication
(10) Pub. No.: US 2026/0218377 A1
(43) Pub. Date: Jul. 30, 2026

(54) METHOD OF FORMING METAL SILICIDE

(71) Applicant: ASM IP Holding B.V., Almere (NL)

(72) Inventors: Jonathan Bakke, Phoenix, AZ (US); Wei Li, Chandler, AZ (US); Sisi Wang, Phoenix, AZ (US)

(21) Appl. No.: 19/459,112

(22) Filed: Jan. 26, 2026

Related U.S. Application Data
(60) Provisional application No. 63/750,956, filed on Jan. 29, 2025.

(51) Int. Cl. C23C 16/42; C23C 16/02; C23C 16/455; H10D 64/01; H10P 14/40

(52) U.S. Cl. CPC C23C 16/42; C23C 16/0245; C23C 16/45553; H10D 64/0112; H10P 14/414

(57) ABSTRACT

Methods of forming a transition metal silicide are disclosed. Exemplary methods include selectively forming a transition metal silicide on a first surface relative to a second surface. The step of forming the transition metal silicide can include providing a catalyst. Additionally or alternatively, exemplary methods can include a cleaning and/or surface treatment step prior to forming the transition metal silicide. Methods described herein may be particularly useful in forming structures suitable for NMOS devices.

### CROSS-REFERENCE TO RELATED APPLICATIONS

This application is a nonprovisional of, and claims priority to and the benefit of, U.S. Provisional Patent Application No. 63/750,956, filed Jan. 29, 2025 and entitled “METHOD OF FORMING METAL SILICIDE,” which is hereby incorporated by reference herein.

### FIELD

The present disclosure relates to methods and apparatus for the manufacture of electronic devices. More particularly, the disclosure relates to methods for forming a silicide on a substrate.

### BACKGROUND

Metal silicides are often used to form contacts to source and drain regions in field effect transistor (FET) devices, such as metal-oxide-semiconductor FET (MOSFET) devices. For n-channel MOSFET (NMOS) devices, a silicide is typically formed by using a plasma-enhanced titanium deposition process to deposit titanium on a Si:P or a SiGe:B surface. In the case of complementary metal-oxide-semiconductor (CMOS) devices, NiPt can be deposited on p-channel metal-oxide semiconductor (PMOS) source and/or drain regions and a plasma-enhanced titanium deposition process can be used to deposit titanium on both the PMOS and NMOS structures.

While using a plasma-enhanced titanium deposition process to deposit titanium can work for a variety of applications, such processes are typically not conformal, are not selective, and require particular hardware for the deposition processes. Thus, such processes can be relatively time consuming and expensive.

Accordingly, improved methods of forming metal silicides are desired. Improved structures formed using such methods are also desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming silicide on a substrate. As set forth in more detail below, methods described herein can be used during the manufacture of electronic devices. Such methods can reduce complexity and/or cost of manufacturing devices, provide conductive layers with reduced contact resistance, provide selective layer deposition techniques, and/or allow for filling vias or other recesses on a substrate surface in a relatively defect-free manner. By way of examples, methods described herein can be used in the formation of memory, logic, other gate-electrode devices, organic light emitting diodes, liquid crystal displays, thin film solar cells, other photovoltaic devices, and the like.

In accordance with examples of the disclosure, a method of forming a structure, such as a structure suitable for use as an NMOS structure, is provided. An exemplary method includes providing a substrate, comprising a semiconductor surface, within a reaction chamber of a reactor, and forming a transition metal silicide layer on the semiconductor surface using a cyclical deposition process. In accordance with examples of the disclosure, the cyclical deposition process includes the steps of providing a pulse of a transition metal precursor to the reaction chamber, providing a pulse of a silicon precursor to the reaction chamber, and providing a catalyst to the reaction chamber. In some cases, the step of providing the catalysts can include a soak process. In accordance with particular examples, a cycle of the cyclical deposition process comprises performing the steps in the following order: A) providing the pulse of the transition metal precursor to the reaction chamber, B) providing the pulse of the silicon precursor to the reaction chamber, and C) providing the catalyst to the reaction chamber. The transition metal can include Nb, Ti, Mo, Hf, Pd, Mo, Ni, V, and/or Pt. The catalyst can include one or more group 13 elements (e.g., Al) and/or La, Mg, Sc, or Y. Exemplary methods can additionally include a degas step prior to the step of forming the transition metal silicide layer. Additionally or alternatively, exemplary methods can include a clean step prior to the step of forming the transition metal silicide layer. In accordance with further examples, the method can be carried out in a reactor system that includes a plurality of process modules. For example, a clean can be performed within a first process module of a reactor system and forming a transition metal silicide layer can be performed within a second module of the reactor system. Degas and/or other steps can be performed in other process modules. Exemplary methods can include steps of forming a cap layer and/or depositing a bulk metal layer.

In accordance with additional examples of the disclosure, a method of forming a structure (e.g., suitable for use as an NMOS structure) includes providing a substrate, comprising a semiconductor surface, within a reaction chamber of a reactor, performing a plasma treatment, and forming a transition metal silicide layer on the semiconductor surface using a cyclical deposition process. Forming the transition metal silicide layer can include (e.g., in the following order) providing a pulse of a transition metal precursor to the reaction chamber, providing a pulse of a silicon precursor to the reaction chamber, and optionally providing a catalyst to the reaction chamber. Methods in accordance with these embodiments include a plasma treatment and need not, but can, include providing a catalyst.

In accordance with yet additional examples, a system is provided. An exemplary system is configured to perform a method as described herein. For example, a system can include a clean module, a deposition module, and a controller configured to cause the system to move a substrate from the clean module to the deposition module and to perform the method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF DRAWINGS

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a structure in accordance with examples of the disclosure.

FIG. 3 illustrates another structure in accordance with examples of the disclosure.

FIG. 4 illustrates another method in accordance with exemplary embodiments of the disclosure.

FIG. 5 illustrates an exemplary reactor system in accordance with examples of the disclosure.

FIG. 6 illustrates another exemplary reactor system in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, and systems provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide methods for forming a structure, such as a structure suitable as an NMOS structure. Exemplary methods can be used to, for example, selectively form a metal silicide on one surface of a substrate. Additionally or alternatively, exemplary methods can be used to form a metal silicide on a relatively clean (e.g., having a (e.g., native) oxide removed) surface. Methods described herein can be used to form a metal silicide to reduce contact resistance of a layer comprising a transition metal. Additionally or alternatively, methods can be employed to form a transition metal silicide using a relatively simple process and/or with reduced equipment requirements. Further, in at least some cases, the metal silicide can be formed at a relatively low temperature.

Metal silicide formed in accordance with a method described herein may be particularly well suited for back end of line and middle end of line processing of electronic devices, such as semiconductor devices. By way of particular examples, methods described herein can be used during the formation of logic devices and memory devices, such as dynamic random access memory (DRAM) devices.

In this disclosure, gas can include material that is a gas at normal temperature and pressure (NTP), a vaporized solid and/or a vaporized liquid, and can be constituted by a single gas or a mixture of gases, depending on the context.

The terms precursor and reactant can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, a transition metal precursor includes a gas or a material that can become gaseous and that can be represented by a chemical formula that includes transition metal. An oxygen-free transition metal precursor includes a transition metal compound that does not include oxygen in its chemical formula.

As used herein, a silicon precursor includes a gas or a material that can become gaseous and that can be represented by a chemical formula that includes silicon.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material or high k dielectric material is material having a dielectric constant greater than the dielectric constant of silicon dioxide.

As used herein, a structure can be or include a substrate as described herein. Structures can include a substrate and one or more layers overlying the substrate, such as one or more layers formed by a method according to the current disclosure. The structure may include or be used in the formation of, for example, a contact or a local interconnect in MEOL processing. The structure may also be used to form a layer in a gate electrode, a buried power rail in logic applications, as well as a word line or a bit line in an advanced memory application.

As used herein, the term film and/or layer can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

The term cyclic deposition process or cyclical deposition process can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term purge can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be effected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. Further, in this disclosure, the terms comprising, including, constituted by and having refer independently to typically or broadly comprising, comprising, consisting essentially of, or consisting of in some embodiments.

In this disclosure, any defined meanings do not necessarily exclude ordinary and customary meanings, in some embodiments.

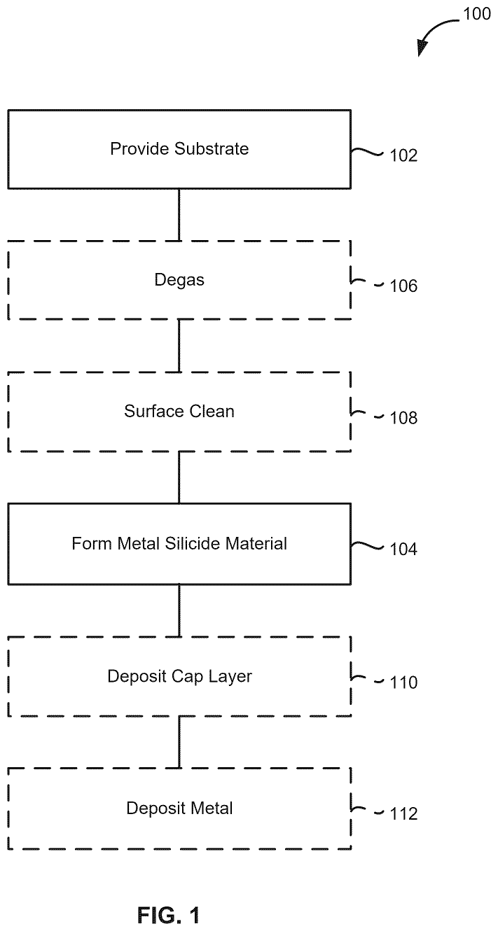

Turning now to the figures, FIG. 1 illustrates a method 100 in accordance with embodiments of the disclosure. Method 100 includes the steps of providing a substrate within a reaction chamber (step 102), (e.g., selectively) forming a transition metal silicide layer (step 104), optionally performing a degas step (step 106), optionally performing a surface clean (step 108), optionally forming a capping layer (step 110), and optionally (e.g., selectively) depositing a metal layer (step 112).

During step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool, such as a cluster tool described in more detail below. The reaction chamber can include a substrate heater to heat a substrate to a temperature noted herein. Additionally or alternatively, the reaction chamber can include rapid thermal processing apparatus, such as lamps, to heat the substrate.

The substrate provided during step 102 can include a first surface and a second surface. The first surface can include a first material and the second surface can include a second material different than the first material. For example, the first material can be or include silicon, silicon germanium, doped silicon (e.g., Si:P), doped silicon germanium (e.g., SiGe:B), or a (e.g., native) oxide thereof. The second material can include, for example, a dielectric material, such as oxides, nitrides, or the like. By way of example, the second material can be or include an interlayer dielectric, such as silicon oxide, silicon nitride, silicon carbonitride, silicon oxycarbide, or the like.

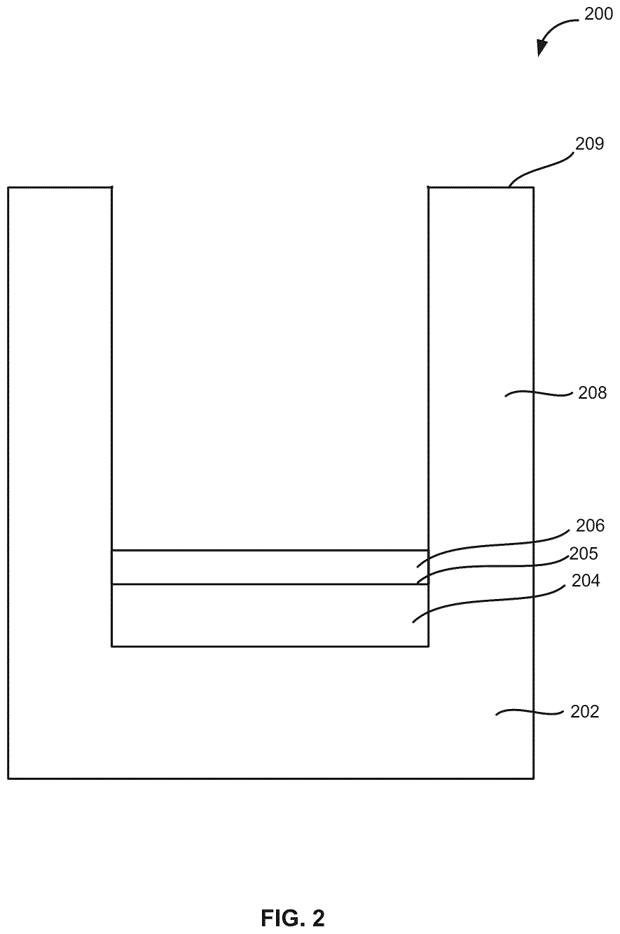

FIG. 2 illustrates a portion or section of a substrate 200 suitable for use as a substrate provided during step 102. Substrate 200 includes a first surface 205 on a first material 204 and a second surface 209 on a second material 208. First material 204 and second material 208 can be as described above. First surface 205 can be or include the first material or a (e.g., native) oxide 206 thereon. As illustrated in FIG. 2, no liner or barrier layer may be present, such that a transition metal silicide layer and subsequently formed metal layer can be in direct contact with second material 208, as well as first material 204. This allows for obtaining a low contact resistance and/or relatively less complex manufacturing, compared to typical processing that requires a barrier layer between a metal and, for example, an interlayer dielectric layer.

Step 102 can include heating the substrate to a desired deposition temperature within the reaction chamber. In some embodiments of the disclosure, step 102 includes heating the substrate to a temperature of less than 650° C. and/or is greater than 400° C. For example, in some embodiments of the disclosure, heating the substrate to a deposition temperature may comprise heating the substrate (e.g., using a substrate heater) to a temperature between about 200° C. and about 500° C., about 250° C. and about 400° C., about 20° C. and about 1000° C., about 400° C. and about 650° C., or about 500° C. and about 600° C.

In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr, about 1 Torr and 100 Torr, or about 1 Torr and 10 Torr.

During step 104, a transition metal silicide layer is (e.g., selectively) deposited onto a first surface (e.g., first surface 205) relative to a second surface (e.g., second surface 209). By depositing metal silicide on first surface 205, the silicide can be formed without consuming first material 204.

In accordance with examples of the disclosure, and referring to FIG. 1, the step of forming a transition metal silicide layer 104 can comprise a cyclical deposition process that includes providing a pulse of a (e.g., oxygen-free) transition metal precursor to the reaction chamber, providing a pulse of a silicon precursor to the reaction chamber; and providing a catalyst to the reaction chamber. The steps of providing the pulse of the transition metal precursor, providing the pulse of a silicon precursor, and providing the catalyst can be repeated. In accordance with examples of these embodiments, a cycle of the cyclical deposition process comprises performing the steps in the following order:
A) providing the pulse of the transition metal precursor to the reaction chamber;
B) providing the pulse of the silicon precursor to the reaction chamber; and
C) providing the catalyst to the reaction chamber.

Performing the steps in this order mitigates formation of contaminants and facilitates formation of a metal silicide.

In some embodiments, the (e.g., oxygen-free) transition metal precursor is provided as a single compound or as a mixture of two or more compounds. In a mixture, the other compound(s), in addition to the transition metal compound, may be or include one or more inert compounds or elements—i.e., inert gases. In some embodiments, the transition metal precursor is provided in a composition. Compositions suitable for use as a precursor can include a transition metal and an effective amount of one or more stabilizing agents and/or inert or carrier gases, such as argon, nitrogen, and/or hydrogen. Compositions may be a solution or a gas at NTP.

In accordance with examples of the disclosure, the transition metal compound or precursor comprises a transition atom and an organic (e.g., hydrocarbon) ligand. The transition metal atom can be or include one or more of Nb, Ti, Mo, Hf, Pd, Mo, Ni, V, and/or Pt. In some embodiments, the transition metal precursor comprises a metal-organic compound comprising a transition metal. In such cases, the transition metal precursor can be referred to as a metal-organic transition metal precursor. A metal-organic transition metal precursor is herein meant to include a transition metal compound comprising a transition metal atom and a hydrocarbon ligand, wherein the transition metal atom is not directly bonded to a carbon atom. In some embodiments, the metal-organic transition metal precursor comprises one transition metal atom, which is not directly bonded with a carbon atom. In some embodiments, the metal-organic transition metal precursor comprises two or more transition metal atoms, none of which is directly bonded to a carbon atom. In some embodiments, the metal-organic transition metal precursor comprises two or more metal atoms, wherein at least one metal atom is not directly bonded to a carbon atom.

In some embodiments, the transition metal precursor comprises an organometallic transition metal compound comprising a transition metal. An organometallic transition metal precursor is herein meant to refer to a transition metal compound comprising a transition metal atom and an organic (e.g., hydrocarbon) ligand, wherein the transition metal atom is directly bonded to a carbon atom. In embodiments in which a transition metal organometallic precursor comprises two or more metal atoms, one or more (e.g., all) of the metal atoms can be directly bonded with a carbon atom. In some embodiments, a transition metal organometallic precursor comprises only one or more transition metals, carbon and hydrogen. In other words, a transition metal organometallic precursor does not contain oxygen, nitrogen or other additional elements. In some embodiments, the transition metal organometallic precursor comprises at least two hydrocarbon ligands. In some embodiments, the transition metal organometallic precursor comprises at least three hydrocarbon ligands. In some embodiments, the transition metal organometallic precursor comprises four hydrocarbon ligands. In some embodiments, the transition metal organometallic precursor comprises a hydrocarbon ligand and a hydride ligand. In some embodiments, the transition metal organometallic precursor comprises a hydrocarbon ligand and two or more hydride ligands. In some embodiments, the transition metal organometallic precursor comprises two hydrocarbon ligands and two hydride ligands. Hydrocarbon ligands as described herein can be or include, for example, C1-C10 hydrocarbons.

In some embodiments, the transition metal precursor comprises one or more cyclic portions. For example, the transition metal precursor may comprise one or more benzene rings. In some embodiments, the transition metal precursor comprises two benzene rings. One or both benzene rings may comprise (e.g., C1-C6) hydrocarbon substituents. In some embodiments, each benzene ring of the transition metal precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert-or sec-form of a butyl, pentyl or hexyl moiety.

In some embodiments, the transition metal precursor comprises a cyclopentadienyl (Cp) ligand. For example, the transition metal precursor may comprise, consist essentially of, or consist of MCp₂Cl₂ or MCp₂H₂, M(iPrCp)₂Cl₂, M(iPrCp)₂H₂, M(EtCp)₂H₂, wherein M represents a transition metal.

In some embodiments, the transition metal precursor comprises a halogenated transition metal compound comprising or consisting of a transition metal and one or more halogen atoms. The transition metal precursor can include one or more ligands noted above and one or more halogen atoms. Alternatively, the transition metal precursor compound can consist of a transition metal and one or more halogen atoms. In some embodiments, the transition metal precursor comprises a transition metal chloride compound, a transition metal iodide compound, or a transition metal bromide compound. As non-limiting examples, the transition metal halide precursor may comprise at least one of: transition metal pentachloride (MCl₅), transition metal hexachloride (MCl₆), transition metal hexafluoride (MF₆), transition metal triiodide (MI₃), or transition metal dibromide (MBr₂), where M is a transition metal, such as one or more of Nb, Ti, Mo, Hf, Pd, Ni, V, Cr, Zr and/or Pt. In some embodiments, the transition metal halide precursor may comprise a transition metal chalcogenide, and in particular embodiments, the transition metal halide precursor may comprise a transition metal chalcogenide halide that does not include oxygen. Exemplary chalcogenides include sulfur, selenium, and tellurium. Other suitable metal precursors that can be used in addition to or in lieu of the transition metal precursor include Er and Yb with the same ligand/compounds noted above.

By way of particular examples, the transition metal precursor can be or include a transition metal halide. Illustrative examples include TaCl₅, NbCl₅, MoCl5, MoO₂Cl₂, TiCl₄, HfCl₄, and/or VCl₄.

A duration of providing the pulse of the transition metal precursor to the reaction chamber during each cycle can be between about 0.1 seconds and about 60 seconds, between about 0.1 seconds and about 10 seconds, or between about 0.5 seconds and about 5 seconds. A flowrate of the transition metal precursor to the reaction chamber can be less than 1000 sccm, or less than 500 sccm, or less than 100 sccm, or less than 10 sccm, or range from about 10 to 2000 sccm, from about 10 to 1000 sccm, or from about 10 to 500 sccm.

The silicon precursor can be or include a compound having a general formula RₐSiX_{b} or R_{c}X_{d}Si—SiR_{c}X_{d}, where each X can be independently selected from H, a halogen, or other ligand, wherein each R can be a C1-C12 organic group, and where a is 0, 1, 2 or 3, b is 4-a, c is 0, 1 or 2, and d is 3-c. R may be a hydrocarbon. If a is two or three, or c is two, each R can be selected independently. In some embodiments, each R is selected from alkyls and aryls. For clarity, X may represent different (e.g., independently selected) ligands. Thus, in some embodiments, an auxiliary reactant may be, for example, a halogen-substituted silane, such as SiH₂Br₂, SiH₂I₂ or SiH₂Cl₂.

In some embodiments, X is a hydrogen, a substituted or an unsubstituted alkyl or aryl or a halogen. In some embodiments, X is H. In some embodiments, X is an alkyl or an aryl. In some embodiments, X is a C1 to C4 alkyl. In some embodiments, X is a substituted alkyl or aryl. In some embodiments, X is a substituted alkyl or aryl, wherein the substituent comprises silicon. In some embodiments, X is selected from a group consisting of H, Me, Et, nPr, iPr, nBu, tBu, M′Me₃, M′Et₃, M′Pr₃, M′Bu₃, Cl, Br, or I, wherein M′ is Si.

In some embodiments, the silicon precursor may have a formula R₃Si_{X} R₂SiX₂, R_{S}iX₃, or SiX₄, where a, b, R and X are as above. In some embodiments, a silicon atom does not comprise four identical substituents. In some embodiments, the silicon precursor is not SiH₄. In some embodiments, the silicon precursor is not SiH₂Me₂. In some embodiments, the silicon precursor is not SiH₂Et₂. In some embodiments, the silicon precursor is not Si₂H₂.

In some cases, exemplary silicon precursors can consist of silicon and hydrogen. For example, the silicon precursor may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎. In some cases, the silicon precursor can be or include a halogen-substituted silane, where one or more H can be substituted with a halogen, such as F, I, Cl, or Br.

In some cases, the silicon precursor can include an amino silane, such as one or more of silanediamine N, N, N′, N-tetraethyl (C₈H₂₂N₂Si), BTBAS (bis(tertiarybutylamino)silane), BDEAS (bis(diethylamino)silane), or TDMAS (tris(dimethylamino)silane), hexakis(ethylamino)disilane (Si₂(NHC₂H₅)₆.

In accordance with further examples of the disclosure, the silicon precursor does not include a compound comprising oxygen. In some cases, step 110 of providing a silicon precursor includes providing another gas, such as a hydrogen-containing gas (e.g., H₂, NH₃, or the like).

A duration of providing the pulse of the silicon precursor during each cycle can be between about 0.1 seconds and about 60 seconds, between about 0.1 seconds and about 10 seconds, or between about 0.5 seconds and about 5 seconds. A flowrate of the silicon precursor to the reaction chamber can be less than 1000 sccm, or less than 500 sccm, or less than 100 sccm, or less than 10 sccm, or range from about 10 to 2000 sccm, from about 10 to 1000 sccm, or from about 10 to 500 sccm.

The catalyst provided during step 104 can include one or more group 13 elements and/or one or more of La, Mg, Sc, or Y. For example, the catalyst can include one or more of Al, La, Mg, Sc, or Y. Exemplary catalysts include metal organic or organometallic compounds. By way of particular examples, the catalyst can be or includeone or more of trimethylaluminium(TMA), triethylaluminium(TEA), triisobutylaluminium (TiBA), tritertiarybutylaluminum (TTBA), and/or other Al organic precursor(s).

A duration of providing the catalyst during each cycle can be between about 0.1 seconds and about 60 seconds, between about 0.1 seconds and about 10 seconds, or between about 0.5 seconds and about 5 seconds. A flowrate of the catalysts to the reaction chamber can be less than 1000 sccm, or less than 500 sccm, or less than 100 sccm, or less than 10 sccm, or range from about 10 to 2000 sccm, from about 10 to 1000 sccm, or from about 10 to 500 sccm.

Step 104 can include a short period of time to deliver the catalyst to the reactor chamber while an exhaust valve is open for a flush period FP to flush the reaction chamber with the catalyst. In some cases, the flush period FP may be omitted. When the reaction chamber is constructed and arranged to accommodate a single substrate, the flush period FP can be between, for example, 1 to 60 or between 2 and 30 seconds.

In accordance with examples of the disclosure, providing the catalyst comprises a soak process, wherein the catalyst is provided to the reactor chamber while not removing the catalyst with a removal pump or reducing a removal rate for a load period LP by closing a removal reaction chamber valve. This results in a pressure buildup of the catalyst in the reaction chamber. This build up may be terminated when the pressure in the reaction chamber reaches a desired pressure. Alternatively, there may be a pressure release valve that opens when the pressure in the reaction chamber increases above a predetermined maximum, which may also end the pressure load period LP.

Subsequently, the catalyst may be maintained residing stationary in the reaction chamber while not providing or removing any catalyst for a soak period SP. This may be done by closing reactor chamber valves. When the reaction chamber is constructed and arranged to accommodate a single substrate, the load period LP can be between 1 and 3000 seconds, between 3 and 1000 seconds, or between 5 and 500 seconds; and the soak period SP can be between 10 and 9000 seconds, between 50 and 5000 seconds, or between 100 and 1000 seconds. A catalyst period may comprise a flush period FP, a load period LP, and/or a soak period SP. In some cases, a flowrate of gas from the reaction chamber to a vacuum source during the soak period is less than a flowrate of gas from the reaction chamber to the vacuum source during forming a transition metal silicide layer. During the whole catalyst period, the catalyst may react with a surface of the substrate.

The transition metal and/or silicon precursor and/or catalyst can be purged from the reaction chamber—e.g., after each pulse and/or upon completion of a step 104 and/or before and/or after each cycle. As noted above, a purge can be effected either in time or in space, or both. Purging times can be, for example, from about 0.01 seconds to about 20 seconds, from about 0.05 seconds to about 20 seconds, or from about 1 second to about 20 seconds, or from about 0.5 seconds to about 10 seconds, or from about 1 second to about 7 seconds. A flowrate of a purge gas to the reaction chamber can be less than 1000 sccm, or less than 500 sccm, or less than 100 sccm, or less than 10 sccm, or range from about 10 to 2000 sccm, from about 10 to 1000 sccm, or from about 10 to 500 sccm.

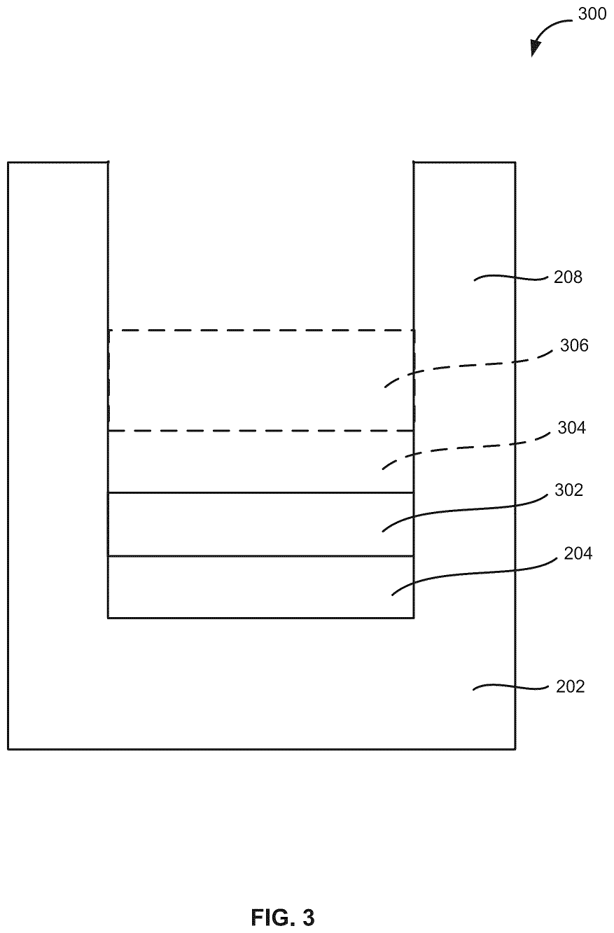

FIG. 3 illustrates a structure 300 after step 104, wherein the transition metal silicide layer 302 is (e.g., selectively) formed within the gap. Structure 300 can be used to form or can comprise an NMOS structure. As illustrated, transition metal silicide layer 302 is (e.g., selectively) formed overlying first surface 205, relative to second surface 209. In this context, selectively formed means a greater amount of transition metal silicide is deposited on first surface 205, relative to second surface 209. In some embodiments of the disclosure, a selectivity of a process can be expressed as a ratio of material deposited (e.g., a layer thickness) on the first surface relative to the amount of material (e.g., a layer thickness) formed on the first and second surfaces combined. For example, if 10 nm of transition metal silicide is deposited on first surface 205 and 1 nm of transition metal silicide is deposited on second surface 209, the selective deposition process will be considered to have 91% selectivity. In some embodiments, the selectivity of the methods disclosed herein is greater than 50%, greater than 75%, greater than 80%, greater than 90%, greater than 95%, greater than 97.5%, greater than 98%, greater than 99%, or even about 100%.

Transition metal silicide layer 302 can comprise, consist essentially of, or consist of transition metal silicide. A layer consisting of transition metal silicide may include an acceptable amount of impurities, such as carbon, chlorine or other halogen, and/or hydrogen that may originate from one or more precursors used to deposit the transition metal silicide layer. As noted above, the transition metal can be or include one or more transition metals selected from the group consisting of Nb, Ti, Mo, Hf, Pd, Mo, Ni, V, Cr, Zr, and/or Pt. By way of particular example, the transition metal can be or include Nb and/or Ti. As noted above, although described in the context of transition metals, in some cases other metals can be used, such as Er an/or Yb.

A thickness of transition metal silicide layer 302 can be, for example, about 1 to about 40 nm or about 2 to about 10 nm. Transition metal silicide layer 302 can comprise, consist essentially of or consist of transition metal and silicon.

In some cases, method 100 can include step 110 of forming a capping layer 304. During step 110, capping layer 304, illustrated in FIG. 3, can be formed (e.g., directly) overlying transition metal silicide layer 302. Capping layer 304 can be or include, for example, a transition metal nitride or a transition metal layer, such as a titanium nitride layer, a molybdenum nitride layer, or a titanium layer.

Capping layer 304 can be formed using a (e.g., selective and/or cyclical) deposition process by providing a metal (e.g., transition metal) precursor and a nitrogen reactant to a reaction chamber. The metal precursor can be or include any transition metal precursor as described herein. The transition metal precursor flowrate and pulse times can be as described above.

The nitrogen reactant can be or include, for example, at least one of ammonia (NH₃), hydrazine (N₂H₄), triazane (N₃H₅), an alkyl substituted hydrazine or triazine, such as tertbutylhydrazine (C4H₉N₂H₃), methylhydrazine (CH₃NHNH₂), dimethylhydrazine ((CH₃)₂N₂H₂), or a nitrogen plasma, wherein a nitrogen plasma includes atomic nitrogen, nitrogen radicals and/or excited nitrogen species.

A duration of a step of providing the nitrogen reactant to the reaction chamber can be between about 0.1 seconds and about 60 seconds, between about 0.1 seconds and about 10 seconds, or between about 0.5 seconds and about 5 seconds. A flowrate of the nitrogen reactant to the reaction chamber can be less than 1000 sccm, or less than 500 sccm, or less than 100 sccm, or less than 10 sccm, or range from about 10 to 2000 sccm, from about 10 to 1000 sccm, or from about 10 to 500 sccm.

A thickness of capping layer 304 can be between about 1 and about 20 nm or between about 2 and about 10 nm. Capping layer 304 can include about 10 to about 90 at% or about 20 to about 70 at % metal and/or about 30 to about 60 at% nitrogen. Alternatively, capping layer 304 can comprise about 100 at % metal.

In accordance with additional examples of the disclosure, method 100 includes depositing a (e.g., bulk) metal layer step 112. Step 112 can be in addition to or in place of step 110.

During step 112, a transition metal, such as molybdenum, can be selectively deposited (e.g., directly) onto capping layer 304 or transition metal silicide layer 302.

Step 112 can include a (e.g., cyclical) deposition process that includes providing a metal (e.g., molybdenum) precursor and a reactant to the reaction chamber. In the method according to the current disclosure, the reactant may be contacted with the substrate comprising a chemisorbed metal (e.g., molybdenum) precursor. The conversion of a metal precursor to metal may take place at the substrate surface. In some embodiments, the conversion may take place at least partially in the gas phase.

The metal precursor, the metal precursor flowrate, and the metal precursor duration during step 112 can be as described above in connection with step 104. Similarly, the temperatures and pressures within a reaction chamber can be as described above in connection with step 104.

Exemplary reactants suitable for use with step 112 include reducing agents. Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, (e.g., C1-C4) alcohols, (e.g., C1-C4) aldehydes, (e.g., C1-C4) carboxylic acids, (e.g., B1-B12) boranes, or an amine. By way of particular examples, the first reactant can be or include at least one of hydrogen (H₂), silane (SiH₄), disilane (Si₂H₆), trisilane (Si₃H₈), germane (GeH₄), digermane (Ge₂H₆), borane (BH₃), or diborane (B₂H₆).

A flowrate of the reactant to the reaction chamber can be greater than zero and less than 30 slm, or less than 15 slm, or less than 10 slm, or less than 5 slm, or less than 1 slm, or even less than 0.1 slm. For example, the flowrate can be between about 0.1 to 30 slm, from about 5 to 15 slm, or equal to or greater than 10 slm. In the case of cyclical deposition processes, the reactant can be pulsed—e.g., for a duration between about 0.01 seconds and about 180 seconds, between about 0.05 seconds and about 60 seconds, or between about 0.1 seconds and about 30 seconds. In some embodiments, metal precursor may be pulsed more than one time, for example, two, three or four times, before a reactant is pulsed to the reaction chamber. Similarly, there may be more than one pulse, such as two, three or four pulses, of a reactant before metal precursor is pulsed (i.e., provided) to the reaction chamber.

In some cases, a purge can be employed to remove any excess reactant and/or reaction byproducts from a reaction chamber—e.g., after a reactant pulse and/or at a completion of a deposition step. The purge can be as described above.

As illustrated in FIGS. 1 and 3, during step 112 of depositing a metal, a layer of metal 306 is (e.g., selectively) formed overlying transition metal silicide layer 302 and/or capping layer 304. Step 112 can be performed within the same reaction chamber as step 104 and/or 110.

The metal (e.g., metal layer 306) may be at least partly in elemental form. Thus, the oxidation state of the metal may be zero. Thus, metal layer 306 may comprise, consist essentially of, or consist of a metal, such as molybdenum.

In some embodiments, a metal layer (e.g., metal layer 306) comprises, for example, about 60 to about 99 atomic percentage (at. %) metal, or about 75 to about 99 at. % metal, or about 75 to about 95 at. % metal, or about 80 to about 95 at. % metal. A metal layer deposited by a method according to the current disclosure may comprise, for example, about 80 at. %, about 83 at. %, about 85 at. %, about 87 at. %, about 90 at. %, about 95 at. %, about 97 at. % or about 99 at. % metal. A layer consisting of metal may include an acceptable amount of impurities, such as carbon, chlorine or other halogen, and/or hydrogen that may originate from one or more precursors used to deposit the metal layer.

In some embodiments, the metal layer may comprise less than about 20 at. %, less than about 15 at. %, less than about 10 at. %, less than about 8 at. %, less than about 6 at. %, less than about 5 at. %, less than about 4.5 at. %, or less than about 3 at. % carbon. A thickness of metal layer 306 can range from about 1 to about 40 nm or about 2 to about 10 nm.

As noted above, method 100 can also include step 106 of performing a degas 106. Step 106 can be performed prior to forming the transition metal silicide layer step 104. In accordance with examples of the disclosure, degas step 106 includes heating the substrate to a temperature of about 200° C. to about 600° C. or about 300° C. to about 500° C. or about 350° C. to about 450° C. A pressure within a chamber during step 106 can be less than 760 Torr or between about 0.1 and 50 Torr or between about 0.5 and 5 Torr. A duration of step 106 can be between about 1 and 30 minutes or between about 5 and 15 minutes.

Method 100 can additionally or alternatively include a clean step 108 prior to the step of forming the transition metal silicide layer 104. Step 108 can be performed within the reaction chamber or within another reaction chamber—e.g., within the same system module. Cleaning step 108 can be used to remove a (e.g., native) oxide from a surface—e.g., from surface 205. During step 108, activated species formed using a fluorine-containing gas and activated species formed using a hydrogen-containing or NH₃-containing gas are formed within or provided to the reaction chamber to form a cleaned surface. Surfaces cleaned in accordance with examples described herein produce higher quality (e.g., less oxygen at an interface) metal silicides, compared to metal silicides formed using, for example, HF as an etchant.

In accordance with examples of the disclosure, activated species formed using a fluorine-containing gas and activated species formed using a hydrogen-containing or NH₃-containing gas to form a cleaned surface are formed using an indirect or remote plasma apparatus. A power used to form a plasma can be about 10 to about 1000 W or about 20 to about 200 W for a 300 mm diameter substrate. A duration of a plasma on-time can be about 1 to about 60 or about 2 to about 10 seconds.

The fluorine-containing gas can be or include, for example, one or more of NF₃, XeF₃, F₂, or the like. A flowrate of the fluorine-containing gas to the remote or indirect plasma apparatus can be about 1 to about 1000 or about 2 to about 100 sccm.

The hydrogen-containing gas can be or include one or more of NH₃, N₂/H₂ (e.g., 10-90 vol. % H₂), hydrazine, a substituted hydrazine and/or triazine as described herein, or the like. A flowrate of the hydrogen-containing gas to the remote or indirect plasma apparatus can be about 1 to about 1000 or about 10 to about 200 sccm.

The fluorine-containing gas and the hydrogen-containing or NH₃-containg gas can be supplied to a plasma apparatus sequentially and/or to separate plasma apparatus or to different regions of a plasma apparatus. The plasma apparatus can include one or more dedicated regions or units, which can be dedicated to forming respective active species. Alternatively, the activated species formed using a fluorine-containing gas and activated species formed using a hydrogen-containing gas can be formed using the same plasma unit or region.

Although not separately illustrated, method 100 can optionally include a step of heating the substrate after step 104, 110, or 112. The substrate can be heated to a temperature of about 550° C. to about 700° C. or about 400° C. to about 900° C.

In some embodiments, a method according to the current disclosure comprises a thermal deposition process. In thermal deposition, the chemical reactions are promoted by increased temperature relevant to ambient temperature. Generally, temperature increase provides the energy for the formation of metal silicide, a capping layer, and/or metal in the absence of other external energy sources, such as plasma, radicals, or other forms of radiation. For example, one or more (e.g., all of steps 104, 110, and 112) can be thermal processes. In some embodiments, the cleaning step (e.g., step 108) includes forming a plasma to form activated species as described above.

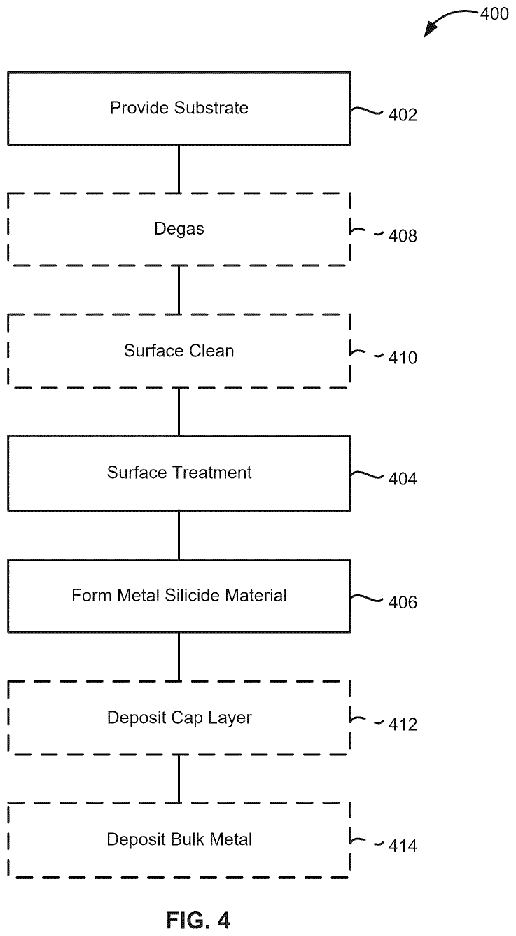

FIG. 4 illustrates another method 400 in accordance with examples of the disclosure. Method 400 includes the steps of providing a substrate within a reaction chamber (step 402), performing a surface treatment (step 404), (e.g., selectively) forming a transition metal silicide layer (step 406) optionally performing a degas step (step 408), optionally performing a surface clean (step 410), optionally forming a capping layer (step 412), and optionally (e.g., selectively) depositing a metal layer (step 414). Method 400 is similar to method 100, except method 400 includes surface treatment step 404 and may not include providing a catalyst during the step of forming the metal silicide.

Steps 402, 408, 410, 412, and 414 can be the same as or similar to corresponding steps 102, 106, 108, 110, and 112 described above.

During step 404, a surface treatment is performed. In accordance with examples of the disclosure, the surface treatment step includes a plasma treatment step. In some cases, the treatment step is a thermal step. By way of example, step 404 includes thermal treatment (e.g., using a hydrogen- and or nitrogen-containing gas (such as gasses including N and/or H described herein), H*/N*(remote) plasma treatment, and/or a TiBA/TTBA soak.

Step 406 can be the same or similar to step 104 described above. However, step 406 need not include a step of providing a catalyst as described above. Step 406 can include forming a transition metal silicide layer on the semiconductor surface using a cyclical deposition process that includes providing a pulse of a transition metal precursor to the reaction chamber, providing a pulse of a silicon precursor to the reaction chamber, and optionally providing a catalyst to the reaction chamber. Each of these steps can be as described above in connection with step 104.

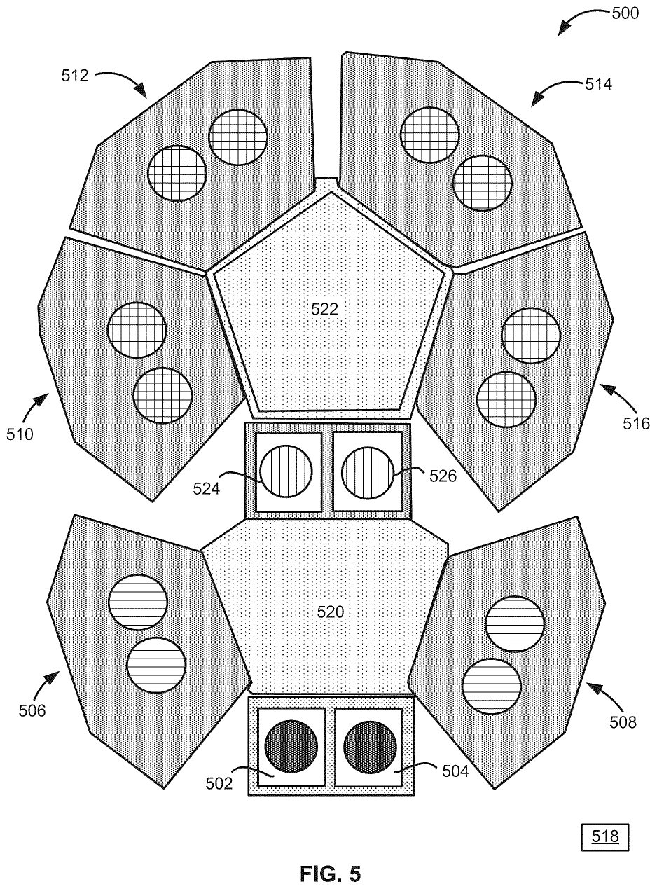

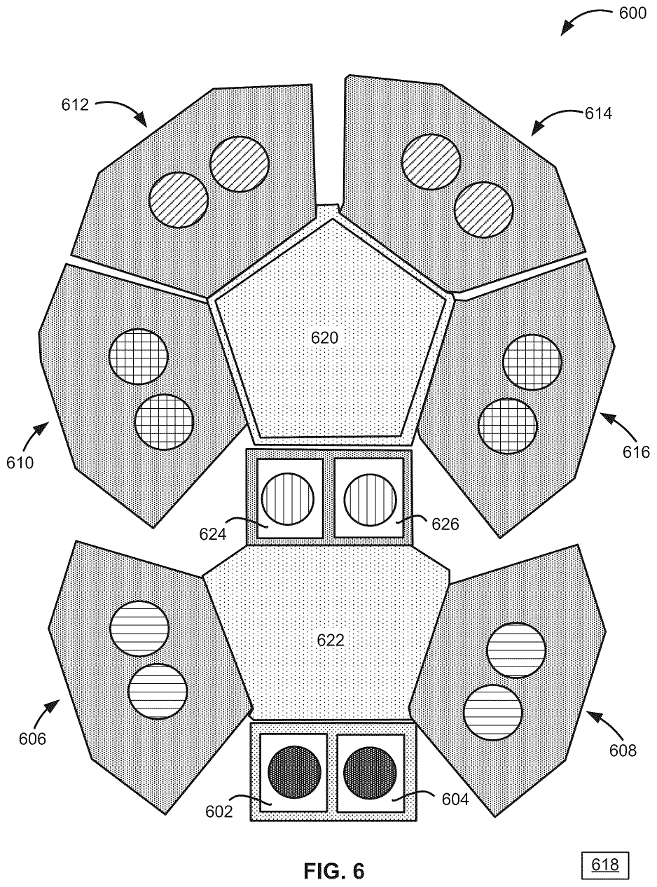

FIGS. 5 and 6 illustrate exemplary systems 500 and 600 in accordance with examples of the disclosure. Systems 500 and 600 can be used to perform various steps of a method (e.g., method 100 or 400) as described herein.

With reference to FIG. 5, system 500 includes degas modules 502, 504, cleaning modules 506, 508, deposition modules 510-516, and a controller 518. System 500 can also include one or more substrate transfer devices 520, 522 to transfer substrates between the various modules and one or more cooling stations 524, 526.

Degas modules 502, 504 can be configured to perform a degas step. For example, degas modules 502, 504 can be configured to perform step 106 or 408.

Cleaning module 506, 508 can be configured to perform a surface clean and/or a surface treatment. For example, cleaning module 506, 508 can be configured to perform one or more of steps 108, 410, and/or 404 as described herein.

Deposition modules 510-516 can be configured to form a transition metal silicide layer on the semiconductor surface and/or to deposit a metal layer overlying the transition metal silicide layer. For example, one or more modules 510-516 can be configured to form the transition metal silicide layer and/or one or more modules 510-516 can be configured to deposit the metal layer.

Controller 518 can be configured to cause system 500 to move substrates between various modules—e.g., using transfer devices 520, 522, and to perform the steps of a method as described herein. By way of particular example, controller 518 can be configured to cause the system to move a substrate from the clean module to the deposition module and form a transition metal silicide layer on the semiconductor surface using a cyclical deposition process within the deposition module.

Cooling stations 524, 526 can be used to cool substrates before processing to a next step of a method or before unloading the substrate from system 500.

System 600 includes degas modules 602, 604, cleaning modules 606, 608, deposition modules 610-616, and a controller 618. System 600 can also include one or more substrate transfer devices 620, 622 to transfer substrates between the various modules and one or more cooling stations 624, 626. System 600 is similar to system 500, except system 600 includes one or more deposition modules 612, 614 to deposit a cap or a metal layer (e.g., perform step 110 or 412).

Controller 618 can be the same or similar to controller 518, except controller 618 can be additionally configured to cause system 600 to deposit a cap or metal layer as described herein. Other system configurations that include modules to perform steps described herein are within the scope of this disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a structure, the method comprising:
providing a substrate, comprising a semiconductor surface, within a reaction chamber of a reactor; and
forming a transition metal silicide layer on the semiconductor surface using a cyclical deposition process, the cyclical deposition process comprising the steps of:
providing a pulse of a transition metal precursor to the reaction chamber;
providing a pulse of a silicon precursor to the reaction chamber; and
providing a catalyst to the reaction chamber.

2. The method of claim 1, wherein, a cycle of the cyclical deposition process comprises performing the steps in the following order:
A) providing the pulse of the transition metal precursor to the reaction chamber;
B) providing the pulse of the silicon precursor to the reaction chamber; and
C) providing the catalyst to the reaction chamber.

3. The method of claim 1, wherein the silicon precursor comprises one or more of a silane or a halogen-substituted silane.

4. The method of claim 1, wherein the transition metal precursor comprises one or more transition metals selected from the group consisting of Nb, Ti, Mo, Hf, Pd, Mo, Ni, V, Cr, Zr, and/or Pt.

5. The method of claim 1, wherein the catalyst comprises one or more group 13 elements and/or one or more of La, Mg, Sc, or Y.

6. The method of claim 1, further comprising a degas step prior to the step of forming the transition metal silicide layer.

7. The method of claim 1, further comprising a clean step prior to the step of forming the transition metal silicide layer.

8. The method of claim 7, wherein the clean step comprises providing activated species formed using a fluorine-containing gas and activated species formed using a hydrogen-containing gas to the reaction chamber.

9. The method of claim 7, wherein the clean step is performed within a first process module of a reactor system and the forming a transition metal silicide layer step is performed within a second module of the reactor system.

10. The method of claim 1, further comprising depositing a metal layer overlying the transition metal silicide layer.

11. The method of claim 10, wherein the metal layer comprises a transition metal layer or a transition metal nitride layer.

12. The method of claim 10, wherein the metal layer comprises molybdenum, titanium nitride, or titanium.

13. The method of claim 1, wherein the structure comprises an NMOS structure.

14. The method of claim 1, wherein the substrate comprises a gap, and wherein the transition metal silicide layer is formed within the gap.

15. The method of claim 1, wherein the semiconductor surface comprises one or more of Si:P or SiGe:B.

16. The method of claim 1, wherein providing the catalyst comprises a soak process.

17. The method of claim 16, wherein a flowrate of gas from the reaction chamber to a vacuum source during the soak period is less than a flowrate of gas from the reaction chamber to the vacuum source during forming a transition metal silicide layer step.

18. The method of claim 1, wherein a temperature of a substrate support during forming a transition metal silicide layer is greater than 400 °C.

19. A method of forming a structure, the method comprising:
providing a substrate, comprising a semiconductor surface, within a reaction chamber of a reactor;
performing a plasma treatment; and
forming a transition metal silicide layer on the semiconductor surface using a cyclical deposition process, the cyclical deposition process comprising the steps of:
providing a pulse of a transition metal precursor to the reaction chamber;
providing a pulse of a silicon precursor to the reaction chamber; and
optionally providing a catalyst to the reaction chamber.

20. A system comprising:
a cleaning module;
a deposition module; and
a controller configured to:
cause the system to move a substrate from the clean module to the deposition module; and
perform the method of claim 1 within the deposition module.
